(19) United States
(12) Patent Application Publication
(10) Pub. No.: US 2026/0215298 A1
(43) Pub. Date: Jul. 23, 2026

(54) INTERCONNECT BOARD HAVING DIELECTRIC FRAME AND EMBEDDED ELECTRICALLY CONNECTABLE ENTITY AND SEMICONDUCTOR ASSEMBLY USING THE SAME

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 19/451,415

(22) Filed: Jan. 16, 2026

Related U.S. Application Data
(60) Provisional application No. 63/746,962, filed on Jan. 18, 2025.

(51) Int. Cl. H10W 70/60; H10W 70/09; H10W 70/68; H10W 70/695; H10W 90/10; H10W 90/22

(52) U.S. Cl. CPC H10W 70/618; H10W 70/09; H10W 70/682; H10W 70/695; H10W 90/10; H10W 90/22

(57) ABSTRACT

An interconnect board includes electrically conductive posts, at least one crack-inhibiting dielectric frame, a stress-release dielectric layer, an embedded electrically connectable entity, a first wiring structure and a second wiring structure. The electrically connectable entity is located within a cavity laterally surrounded by the stress-release dielectric layer, and the first and second wiring structures are formed on opposite sides of the stress-release dielectric layer with the first wiring structure electrically connected to the electrically connectable entity. The electrically conductive posts extend through the stress-release dielectric layer and have opposite sides coupled to the first and second wiring structures. The crack-inhibiting dielectric frame can provide a beneficial effect during the deposition of a stress-release dielectric layer, minimizing warpage and improving structural reliability.

### CROSS REFERENCE TO RELATED APPLICATION

### This application claims the benefit of the filing date of U.S. Provisional Application Serial No. 63/746,962filed January 18, 2025. The entirety of said Provisional Application is incorporated herein by reference

### FIELD OF THE INVENTION

The present invention relates to an interconnect board and, more particularly, to an interconnect board with a dielectric frame and an embedded electrically connectable entity and a semiconductor assembly using the same.

### DESCRIPTION OF RELATED ART

High-performance microprocessors and ASICs require substrates that offer high performance and reliability for signal interconnection. However, in conventional resin laminate substrates, the electroplated copper layer is prone to peeling under stringent operational conditions, making these substrates unreliable for practical use. In specific applications, ceramic materials like alumina or aluminum nitride are preferred for their desirable attributes, including excellent electrical insulation, robust mechanical strength, low coefficient of thermal expansion (CTE), and efficient thermal conductivity. Consequently, multi- layer ceramic substrates, such as HTCC (high temperature co-fired ceramic) or LTCC (low temperature co-fired ceramic), have been developed to meet specific application demands.

In addition to the resin laminate substrates and the multi-layer ceramic substrates mentioned above, copper lead frame substrates have emerged as another favored option. They offer distinct advantages such as high thermal conductivity, excellent electrical properties, and straightforward manufacturing processes. However, there remains a critical need for further improvement to address issues such as warpage, cracking, and other related problems. This pursuit of enhancement is pivotal in ensuring the continued advancement and reliability of high-performance semiconductor devices.

### SUMMARYOF THE INVENTION

An objective of the present invention is to provide an interconnect board configured with an embedded electrically connectable entity for required electrical performance and characterized by alleviated warpage. In the manufacture of the interconnect board, a crack-inhibiting dielectric frame is employed to provide a beneficial effect during the deposition of a stress-release dielectric layer, minimizing warpage and improving structural reliability.

In accordance with the foregoing and other objectives, the present invention provides an interconnect board that includes electrically conductive posts, at least one crack-inhibiting dielectric frame, a stress-release dielectric layer, an embedded electrically connectable entity, a first wiring structure and a second wiring structure. The electrically conductive posts are spaced from each other and from the at least one crack-inhibiting dielectric frame. The stress-release dielectric layer laterally covers upper sidewall portions of the electrically conductive posts and an inner periphery of the at least one crack-inhibiting dielectric frame and has inner surrounding sidewalls around a cavity. The embedded electrically connectable entity is disposed within the cavity and includes conductive pads on a top side thereof. The first wiring structure covers the top side of the embedded electrically connectable entity and top surfaces of the electrically conductive posts, the at least one crack-inhibiting dielectric frame and the stress-release dielectric layer and is electrically connected to the conductive pads of the embedded electrically connectable entity and the electrically conductive posts. The second wiring structure covers a bottom side of the embedded electrically connectable entity and bottom surfaces of the electrically conductive posts, the at least one crack-inhibiting dielectric frame and the stress-release dielectric layer and is electrically connected to the electrically conductive posts.

Also, the present invention provides a semiconductor assembly, in which one or more semiconductor devices are disposed above the first wiring structure of the interconnect board and electrically connected to the embedded electrically connectable entity through the first wiring structure.

These and other features and advantages of the present invention will be further described and more readily apparent from the detailed description of the preferred embodiments which follows.

### BRIEF DESCRIPTION OF THE DRAWINGS

The detailed description of the preferred embodiments of the present invention can best be understood when read in conjunction with the following drawings, in which:

FIG. 1 is a cross-sectional view of an electrically and thermally conductive plate in accordance with the first embodiment of the present invention;

FIGS. 2 and 3 are cross-sectional and top perspective views, respectively, of the structure of FIG. 1 further provided with a crack-inhibiting dielectric frame in accordance with the first embodiment of the present invention;

FIGS. 4 and 5 are cross-sectional and top perspective views, respectively, of the structure of FIGS. 2 and 3 further provided with a stress-release dielectric layer in accordance with the first embodiment of the present invention;

FIGS. 6 and 7 are cross-sectional and bottom perspective views, respectively, of the structure of FIGS. 4 and 5 further formed with thermal paddles and electrically conductive posts in accordance with the first embodiment of the present invention;

FIGS. 8 and 9 are cross-sectional and bottom perspective views, respectively, of the structure of FIGS. 6 and 7 further provided with an interfacial dielectric layer in accordance with the first embodiment of the present invention;

FIGS. 10 and 11 are cross-sectional and top perspective views, respectively, of the structure of FIGS. 8 and 9 further formed with cavities in accordance with the first embodiment of the present invention;

FIG. 12 is a cross-sectional view of the structure of FIG. 10 further provided with electrically connectable entities in accordance with the first embodiment of the present invention;

FIG. 13 is a cross-sectional view of the structure of FIG. 12 further provided with first and second dielectric layers in accordance with the first embodiment of the present invention;

FIG. 14 is a cross-sectional view of the structure of FIG. 13 further formed with openings in accordance with the first embodiment of the present invention;

FIG. 15 is a cross-sectional view of the structure of FIG. 14 further provided with first and second conductive traces to finish the fabrication of an interconnect board in accordance with the first embodiment of the present invention;

FIG. 16 is a cross-sectional view of the structure of FIG. 15 further provided with semiconductor devices to finish the fabrication of a semiconductor assembly in accordance with the first embodiment of the present invention;

FIG. 17 is a cross-sectional view of another interconnect board in accordance with the second embodiment of the present invention;

FIG. 18 is a cross-sectional view of the structure of FIG. 17 further provided with semiconductor devices and solder balls in accordance with the first embodiment of the present invention;

FIGS. 19 and 20 are cross-sectional and top perspective views, respectively, of the structure of FIG. 1 further provided with outer and inner crack-inhibiting dielectric frames in accordance with the third embodiment of the present invention;

FIG. 21 is a cross-sectional view of an interconnect board fabricated from the structure of FIG. 19 in accordance with the third embodiment of the present invention;

FIG. 22 is a cross-sectional view of another aspect of the interconnect board in accordance with the third embodiment of the present invention; and

FIG. 23 is a cross-sectional view of another interconnect board in accordance with the fourth embodiment of the present invention.

### DETAILED DESCRIPTION OF THE PREFERRED EMBODIMENTS

Hereafter, examples will be provided to illustrate the embodiments of the present invention. The advantages and effects of the invention will become more apparent from the following description of the present invention. It should be noted that the accompanying figures are simplified and illustrative. The quantity, shape and size of components shown in the figures may be modified according to practical conditions, and the arrangement of components may be more complex. Other various aspects may also be practiced or applied in the invention, and various modifications and variations can be made without departing from the spirit of the invention based on various concepts and applications.

### Embodiment 1

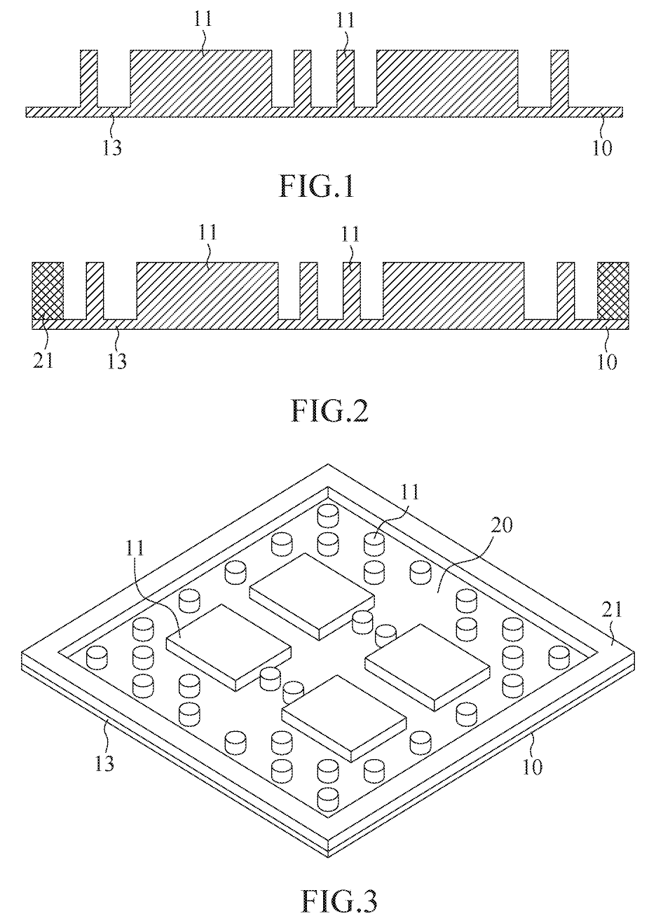

FIGS. 1- 15 are schematic views showing a method of making an interconnect board that includes thermal paddles, electrically conductive posts, embedded electrically connectable entities, a crack-inhibiting dielectric frame, a stress-release dielectric layer, an interfacial dielectric layer, a first wiring structure and a second wiring structure in accordance with the first embodiment of the present invention.

FIG. 1 is a cross-sectional view of an electrically and thermally conductive plate 10 formed with an array of protrusions 11 projecting from a base 13 by, for example, one-sided etching or plating. The electrically and thermally conductive plate 10 can have a thickness (namely, a combined thickness of the protrusion 11 and the base 13) ranging from, for example, 0.15 mm to 0.5 mm, and typically is made of copper, aluminum, alloy 42, iron, nickel, silver, gold, combinations thereof, alloys thereof or any other suitable metals. In this embodiment, the electrically and thermally conductive plate 10 is made of copper with a thickness of about 0.25 mm, and the thickness of the base 13 is illustrated as 0.05 micrometers.

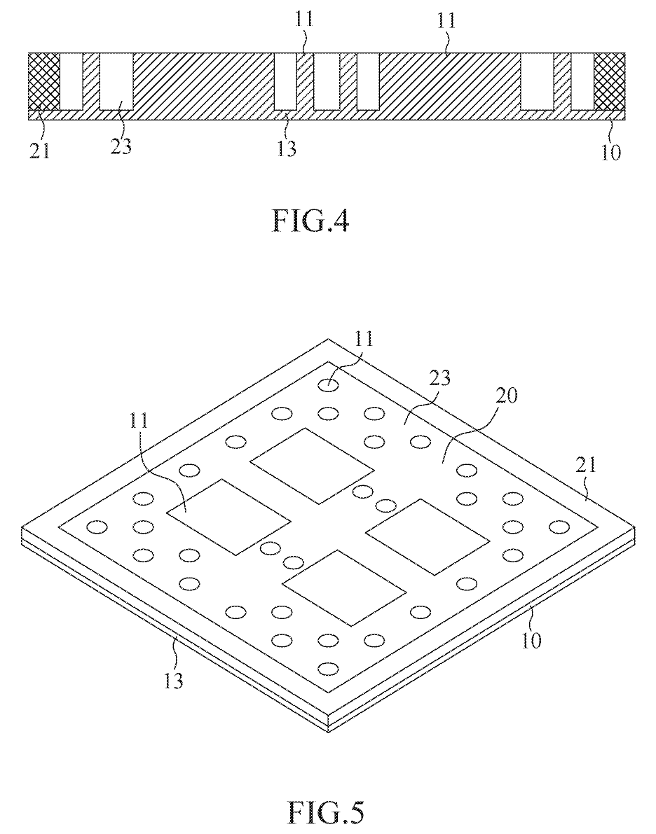

FIGS. 2 and 3 are cross-sectional and top perspective views, respectively, of the structure provided with a crack-inhibiting dielectric frame 21. The crack-inhibiting dielectric frame 21 may have an elastic modulus lower than 50 Gpa and is deposited and attached on the base 13 from above to define a compartment 20. In practice, the structure is typically manufactured in a multi-compartment form (not shown in the figures), which contains a plurality of separate compartments 20 defined by the crack-inhibiting dielectric frame 21. For instance, the compartments 20 may be arranged into an N x M array, such as a 2 x 2 array, and these protrusions 11 are present in the same quantity and arrangement within each compartment 20. Preferably, the crack-inhibiting dielectric frame 21 contains reinforcement to enhance the functionality of suppressing crack propagation through the crack-inhibiting dielectric frame 21. For instance, the crack-inhibiting dielectric frame 21 may be made of an organic material (such as epoxy-based material) with glass reinforcement (such as fiberglass). In this illustration, the top surface of the crack-inhibiting dielectric frame 21 is substantially coplanar with the top surfaces of the protrusions 11. By using a crack-inhibiting dielectric frame 21 with an elastic modulus lower than 50 GPa, instead of a conventionally used metal frame, the structural warpage caused by the subsequent resin deposition process can be suppressed.

FIGS. 4 and 5 are cross-sectional and top perspective views, respectively, of the structure provided with a stress-release dielectric layer 23. The stress-release dielectric layer 23 is filled into remaining spaces within the compartment 20 to cover sidewalls of the protrusions 11 and the top surface of the base 13 and an inner periphery of the crack-inhibiting dielectric frame 21. The capability of the stress-release dielectric layer 23 to absorb stress helps further alleviate warpage. For instance, the stress-release dielectric layer 23 may have an elastic modulus lower than 30 Gpa. Additionally, the stress-release dielectric layer 23 may contain electrically insulative fillers with a coefficient of thermal expansion (CTE) less than 20 ppm dispersed in an organic material (such as epoxy-based material). This facilitates the alleviation of internal expansion and shrinkage of the stress-release dielectric layer 23 during thermal cycling, thereby restraining resin cracking. In this illustration, the top surface of the stress-release dielectric layer 23 is substantially coplanar with the top surfaces of the protrusions 11 and the crack-inhibiting dielectric frame 21.

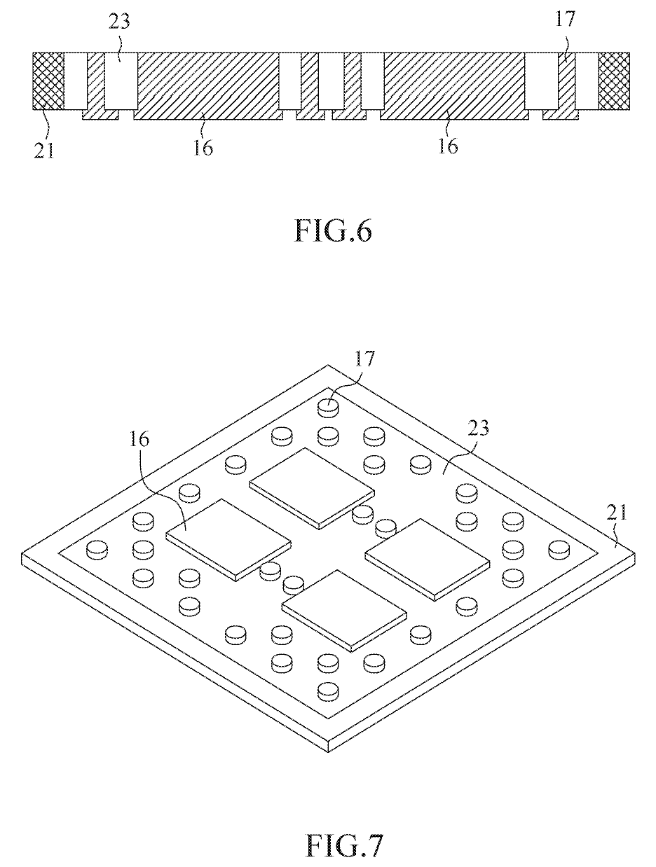

FIGS. 6 and 7 are cross-sectional and bottom perspective views, respectively, of the structure formed with one or more thermal paddles 16 (e.g. four thermal paddles illustrated in FIG. 7) and electrically conductive posts 17. The base 13 of the electrically and thermally conductive plate 10 is patterned by, for example, etching, to leave selected portions of the base 13 each integrated with a respective one of the protrusions 11. Accordingly, the thermal paddles 16 and the electrically conductive posts 17 are formed and have lower portions spaced from each other by gaps, and the bottom surface of the stress-release dielectric layer 23 has selected portions exposed from the gaps. The metal patterning techniques include wet etching, electro-chemical etching, laser-assisted etching, and their combinations with etch masks (not shown) thereon. Each of the thermal paddles 16 and the electrically conductive posts 17 has upper sidewall portions laterally covered by and surrounded by the stress-release dielectric layer 23 and lower sidewall portions laterally surrounded by the gaps.

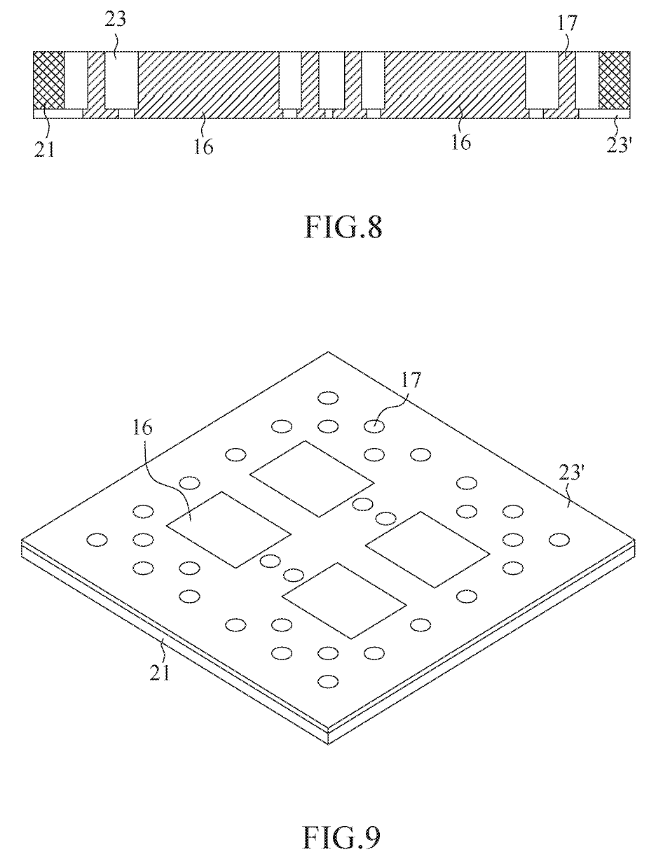

FIGS. 8 and 9 are cross-sectional and bottom perspective views, respectively, of the structure provided with an interfacial dielectric layer 23’. Optionally, the interfacial dielectric layer 23’ is filled into the gaps to cover the lower sidewall portions of the thermal paddles 16 and the electrically connective posts 17. The interfacial dielectric layer 23’ may be made of the same material as the stress-release dielectric layer 23. In this illustration, the bottom surface of the interfacial dielectric layer 23’ is substantially coplanar with the bottom sides of the thermal paddles 16 and the bottom surfaces of the electrically connective posts 17.

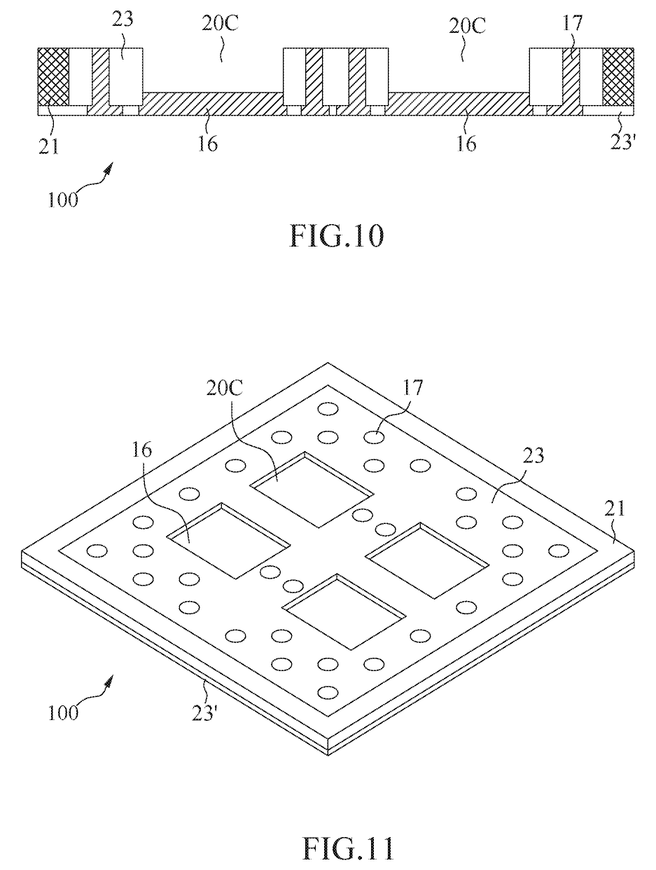

FIGS. 10 and 11 are cross-sectional and top perspective views, respectively, of the structure formed with one or more cavities 20C (e.g. four cavities as shown in FIG. 11). The thermal paddles 16 are partially removed by, for example, etching, from above to form the cavities 20C laterally surrounded by the stress-release dielectric layer 23. In this illustration, the depth of the cavities 20C is less than the thickness of the stress-release dielectric layer 23, and the stress-release dielectric layer 23 has inner surrounding sidewalls exposed from the cavities 20C. As a result, each of the thermal paddles 16 has a recessed surface as a heat conduction surface at a level between the top and bottom surfaces of the electrically conductive posts 17, and each of the cavities 20C is defined by the recessed surface of the respective thermal paddle 16 as a bottom of the cavity 20C and the lateral surfaces of the stress-release dielectric layer 23.

At this stage, a thermally enhanced cavity substrate 100 is accomplished and includes the crack-inhibiting dielectric frame 21, the thermal paddles 16, the electrically conductive posts 17, the stress-release dielectric layer 23 and the interfacial dielectric layer 23’.

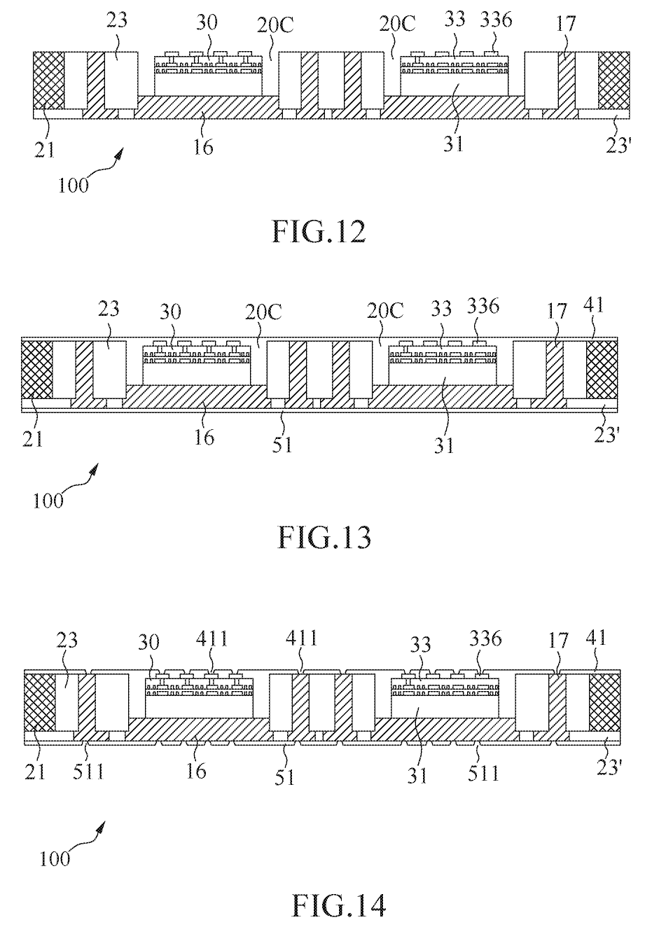

FIG. 12 is a cross-sectional view of the structure provided with electrically connectable entities 30 attached to the thermally enhanced cavity substrate 100 illustrated in FIG. 10. Each of the cavities 20C is occupied by one of the electrically connectable entities 30 which is mounted and superimposed over the heat conduction surface of the respective thermal paddle 16. In this illustration, each of the electrically connectable entities 30 placed in the respective cavity 20C has a top side substantially coplanar with the top surfaces of the electrically conductive posts 17, the crack-inhibiting dielectric frame 21 and the stress-release dielectric layer 23. The electrically connectable entities 30 can be individually selected from active components (such as transistors, diodes and the like), passive components (such as capacitors, resistors, inductors and the like) or others, depending on the design or function needed. In this embodiment, the electrically connectable entities 30 are illustrated as wiring bridges, each including a routing structure 33 to provide conductive pads 336 on its top side. More specifically, the routing structure 33 can be formed on a carrier plate 31 (such as a silicon-based carrier plate) and includes multi-layer routing traces, with the outmost layer configured with the conductive pads 336. The carrier plate 31 of the electrically connectable entity 30 is superimposed over and attached onto the heat conduction surface of the respective thermal paddle 16.

FIG. 13 is a cross-sectional view of the structure provided with a first dielectric layer 41 and a second dielectric layer 51 to cover the thermally enhanced cavity substrate 100 and the electrically connectable entities 30 from above and below, respectively. The first dielectric layer 41 extends laterally above the top sides of the electrically connectable entities 30 and the top surfaces of the crack-inhibiting dielectric frame 21, the electrically conductive posts 17 and the stress-release dielectric layer 23. Portions of the first dielectric layer 41 further extend into the remaining space within the cavities 20C and conformally coats the peripheral edges of the electrically connectable entities 30 and the inner surrounding sidewalls of the stress-release dielectric layer 23. The second dielectric layer 51 extends laterally below the bottom sides of the thermal paddles 16 and the bottom surfaces of the electrically conductive posts 17 and the interfacial dielectric layer 23’. The first and second dielectric layers 41 and 51 may have an elastic modulus lower than 50 Gpa and preferably contains reinforcement to avoid crack propagation through the first and second dielectric layers 41 and 51. For instance, the first and second dielectric layers 41 and 51 may be made of an organic material (such as epoxy-based material) with glass reinforcement (such as fiberglass). The glass reinforcement can create fiber-interlocking structures above and below the electrically connectable entities 30 and the thermally enhanced cavity substrate 100, while portions of the organic material of the first dielectric layer 41 further extends into the remaining spaces within the cavities 20C and between the electrically connectable entities 30 and the stress-release dielectric layer 23.

FIG. 14 is a cross-sectional view of the structure provided with first and second openings 411 and 511 to expose selected portions of the electrically conductive posts 17 and the conductive pads 336 of the electrically connectable entities 30 from above and selected portions of the thermal paddles 16 and the electrically conductive posts 17 from below. The first and second openings 411 and 511 can be formed by numerous techniques including laser drilling, plasma etching and photolithography. Laser drilling can be enhanced by a pulsed laser. Alternatively, a scanning laser beam with a metal mask can be used. The first openings 411 extend through the first dielectric layer 41 and are aligned with the selected portions of the electrically conductive posts 17 and the conductive pads 336 of the electrically connectable entities 30. The second openings 511 extend through the second dielectric layer 51 and are aligned with the selected portions of the thermal paddles 16 and the electrically conductive posts 17.

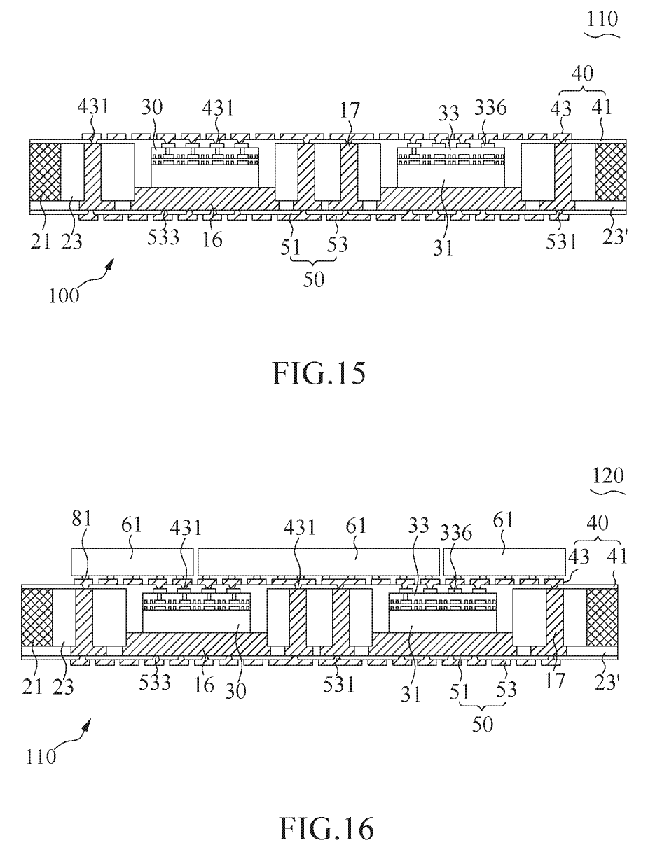

FIG. 15 is a cross-sectional view of the structure provided with first conductive traces 43 on the first dielectric layer 41 and second conductive traces 53 under the second dielectric layer 51 by metallization and metal patterning process. The first conductive traces 43 include first conductive vias 431 for electrical connection with the electrically conductive posts 17 and the electrically connectable entities 30. The first conductive vias 431 extend through the first dielectric layer 41 and contact the conductive pads 336 of the electrically connectable entities 30 and the electrically conductive posts 17. The second conductive traces 53 include second conductive vias 531 for electrical connection with the electrically conductive posts 17 and thermal vias 533 for thermal conduction with the thermal paddles 16. The second conductive vias 531 and the thermal vias 533 extend through the second dielectric layer 51 and contact the electrically conductive posts 17 and the thermal paddles 16, respectively.

The metallization can be executed by numerous techniques, such as electroplating, electroless plating, evaporating, sputtering or their combinations, and typically by electroless plating followed by electroplating. The metal patterning techniques include wet etching, electro-chemical etching, laser-assisted etching, and their combinations with etch masks (not shown) thereon that define the first and second conductive traces 43 and 53.

At this stage, an interconnect board 110 is accomplished and includes the thermally enhanced cavity substrate 100, the electrically connectable entities 30 embedded in the cavities 20C of the thermally enhanced cavity substrate 100, and first and second wiring structures 40 and 50 on both sides of the thermally enhanced cavity substrate 100, respectively. The first wiring structure 40 is configured to be in electrical connection with the electrically conductive posts 17 and the electrically connectable entities 30, and includes the first dielectric layer 41 and the first conductive traces 43. The second wiring structure 50 is configured to be in electrical connection with the electrically conductive posts 17 and in thermal conduction with the thermal paddles 16, and includes the second dielectric layer 51 and the second conductive traces 53. As a result, the embedded electrically connectable entities 30 enable reliable electrical communication between devices coupled to the first wiring structure 40, while the thermal paddles 16, which are in thermal conduction with the second wiring structure 50, provide heat conduction paths for the embedded electrically connectable entities 30.

FIG. 16 is a cross-sectional view of the structure provided with semiconductor devices 61 to finish the fabrication of a semiconductor assembly 120. The semiconductor devices 61 are attached to and electrically connected to the first conductive traces 43 by soldering materials 81 between the semiconductor devices 61 and first conductive traces 43. As a result, the semiconductor devices 61 can be electrically connected to the embedded electrically connectable entities 30 through the soldering materials 81 and the first wiring structure 40 and to the second wiring structure 50 through the soldering materials 81, the first wiring structure 40 and the electrically conductive posts 17.

### Embodiment 2

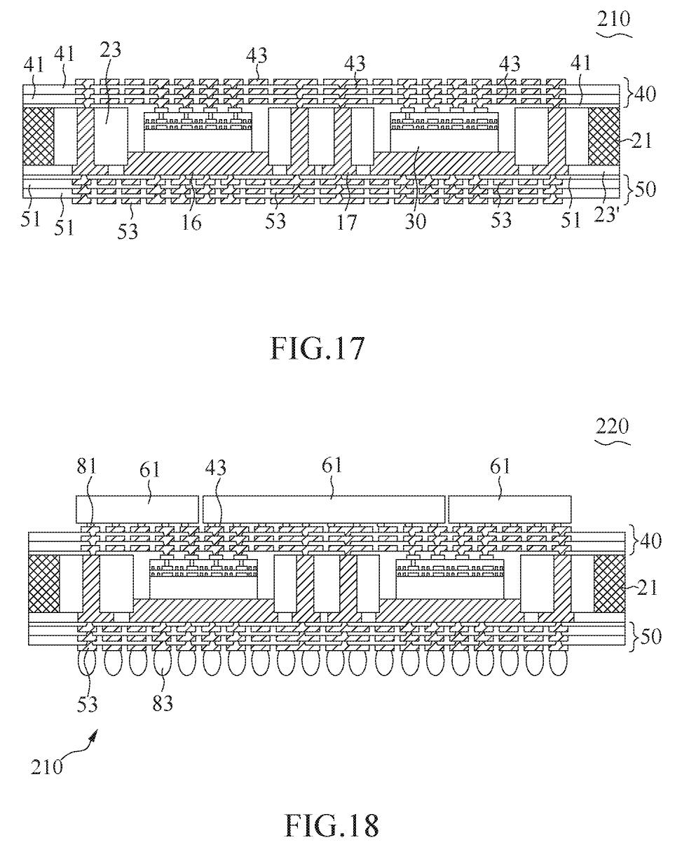

FIG. 17 is a cross-sectional view of an interconnect board in accordance with the second embodiment of the present invention. For purposes of brevity, any description in the Embodiment above is incorporated herein insofar as the same is applicable, and the same description need not be repeated.

The interconnect board 210 of this embodiment is similar to that illustrated in FIG. 15, except that the first wiring structure 40 and the second wiring structure 50 are multi-layer circuitry structures. More specifically, in this embodiment, the first wiring structure 40 includes multiple first dielectric layers 41 and multi-layer first conductive traces 43 serially formed in an alternate fashion, while the second wiring structure 50 includes multiple second dielectric layers 51 and multi-layer second conductive traces 53 serially formed in an alternate fashion.

FIG. 18 is a cross-sectional view of the structure provided with semiconductor devices 61 and solder balls 83 to finish the fabrication of a semiconductor assembly 220. The semiconductor devices 61 are attached to and electrically connected to the outmost first conductive traces 43 by soldering materials 81 between the semiconductor devices 61 and the outmost first conductive traces 43. The solder balls 83 are mounted on the outmost second conductive traces 53 of the second wiring structure 50.

### Embodiment 3

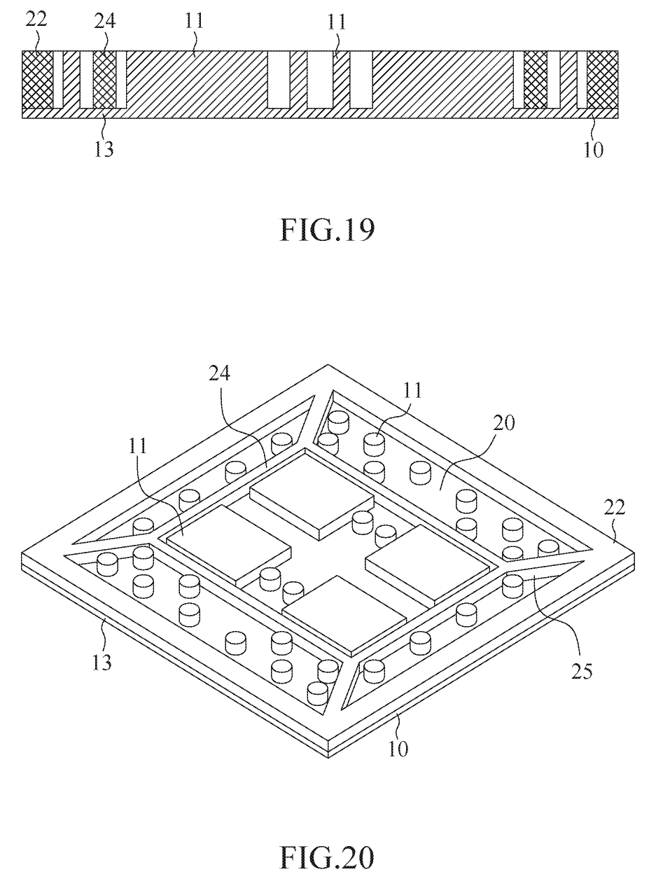

FIGS. 19-21 are schematic views showing a method of making an interconnect board in accordance with the third embodiment of the present invention. For purposes of brevity, any description in above Embodiments is incorporated herein insofar as the same is applicable, and the same description need not be repeated.

FIGS. 19 and 20 are cross-sectional and top perspective views, respectively, of the structure with an outer crack-inhibiting dielectric frame 22 and an inner crack-inhibiting dielectric frame 24 deposited and attached onto the electrically and thermally conductive plate 10 of FIG. 1. In this illustration, the inner crack-inhibiting dielectric frame 24 is encircled by, surrounded by and spaced from the outer crack-inhibiting dielectric frame 22 and integrated with the outer crack-inhibiting dielectric frame 22 by tie bar 25.

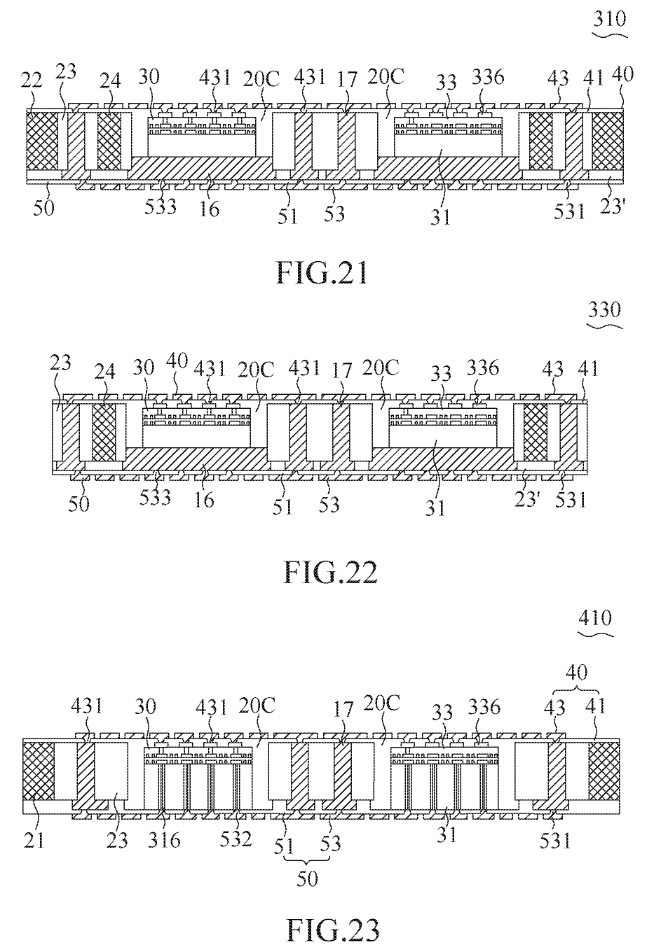

FIG. 21 is a cross-sectional view of an interconnect board fabricated from the structure shown in FIG. 19. The steps for manufacturing the interconnect board 310 includes dispensation of the stress-release dielectric layer 23, partial removal of the base 13, dispensation of the interfacial dielectric layer 23’, formation of the cavities 20C, attachment of the electrically connectable entities 30 and formation of first and second wiring structures 40 and 50 as illustrated in Embodiment 1. In this embodiment, by increasing the number of crack-inhibiting dielectric frames relative to Embodiment 1, warpage control can be further improved.

FIG. 22 is a cross-sectional view of another aspect of the interconnect board 330 in accordance with the third embodiment of the present invention. The interconnect board 330 is similar to that illustrated in FIG. 21, except that it is devoid of the outer crack-inhibiting dielectric frame. Although not explicitly depicted herein, it will be appreciated that when the interconnect board is manufactured in panel scale, a singulation process would be performed to obtain individual interconnect boards, either with the outer crack-inhibiting dielectric frame 22 entirely removed, as illustrated in FIG. 22, or with a portion of the outer crack-inhibiting dielectric frame 22 retained.

### Embodiment 4

FIG. 23 is a cross-sectional view of an interconnect board in accordance with the fourth embodiment of the present invention. For purposes of brevity, any description in the Embodiments above is incorporated herein insofar as the same is applicable, and the same description need not be repeated.

The interconnect board 410 of this embodiment is similar to that illustrated in FIG. 15, except that the thermal paddles 16 are removed during cavity formation, no interfacial dielectric layer 23’ is provided, and the second wiring structure 50 is further electrically connected to metallized through-vias 316 of the embedded electrically connectable entities 30. The metallized through-vias 316 extend through the carrier plate 31 of the electrically connectable entity 30 and are configured to be in electrical connection with the routing structure 33. The second dielectric layer 51 extends laterally below the bottom sides of the embedded electrically connectable entities 30 and the bottom surfaces of the stress-release dielectric layer 23 and the crack-inhibiting dielectric frame 21, and covers and conformally coats the lower sidewall portions of the electrically connective posts 17. In this illustration, the embedded electrically connectable entities 30 are attached on selected portions of the second dielectric layer 51 that form bottoms of the cavities 20C, and laterally surrounded by inner lateral surfaces of the stress-release dielectric layer 23 and the second dielectric layer 51. The second conductive traces 53 further includes additional second conductive vias 532 in connection with the metallized through-vias 316. As a result, the metallized through-vias 316 provide connection between the routing structures 33 of the embedded electrically connectable entities 30 and the second wiring structure 50.

The thermally enhanced cavity substrates, interconnect boards and assemblies described above are merely exemplary. Numerous other embodiments are contemplated. In addition, the embodiments described above can be mixed-and-matched with one another and with other embodiments depending on design and reliability considerations. The electrically connectable entity can share or not share the cavity with other electrically connectable entities. For instance, a cavity can accommodate a single electrically connectable entity, or numerous electrically connectable entities can be placed within a single cavity.

As illustrated in the aforementioned embodiments, a distinctive interconnect board is configured to exhibit improved reliability and electrical performance. The interconnect board mainly includes electrically conductive posts, a stress-release dielectric layer, an electrically connectable entity, at least one crack-inhibiting dielectric frame, an embedded electrically connectable entity, a first wiring structure, a second wiring structure, optionally a thermal paddle, and optionally an interfacial dielectric layer. In practice, an un-singulated interconnect board may first be manufactured at panel scale with a plurality of unit interconnect boards partitioned by the crack-inhibiting dielectric frame and then subjected to a singulation process to obtain a plurality of singulated interconnect boards. The at least one crack-inhibiting dielectric frame in a singulated interconnect board may include an outer crack-inhibiting dielectric frame and/or an inner crack-inhibiting dielectric frame. The outer crack-inhibiting dielectric frame can have at least one inner periphery each located around a compartment, and the electrically conductive posts, the stress-release dielectric layer, and the embedded electrically connectable entity are accommodated in the compartment. The inner crack-inhibiting dielectric frame may have inner and outer peripheries laterally covered by the stress-release dielectric layer. In embodiments where both an outer crack-inhibiting dielectric frame and an inner crack-inhibiting dielectric frame are present in a singulated interconnect board, the inner crack-inhibiting dielectric frame is encircled by and spaced from the outer crack-inhibiting dielectric frame.

In the manufacturing of the panel-scaled interconnect board, crack-inhibiting dielectric frames are used instead of conventionally used metal frames to create a plurality of distinct compartments. The top surface of the crack-inhibiting dielectric frame may be substantially coplanar with the top surfaces of the electrically conductive posts. Compared to the commonly used metal frame, the crack-inhibiting dielectric frame typically has an elastic modulus lower than 50 Gpa and can reduce warpage caused by resin filling. Preferably, the crack-inhibiting dielectric frame is made from a filler-free organic material to prevent filler particles from contributing to the frame's susceptibility to cracking. More preferably, the crack-inhibiting dielectric frame is made of an organic material containing reinforcement configured to suppress crack propagation.

The stress-release dielectric layer laterally surrounds a cavity and laterally covers and contacts and conformally coats sidewalls of the electrically conductive posts as well as the inner periphery of the crack-inhibiting dielectric frame. In one or more embodiments, the stress-release dielectric layer laterally covers and contacts and conformally coats upper portions of the sidewalls of the electrically conductive posts, while the optional interfacial dielectric layer laterally covers and contacts and conformally coats lower portions of the sidewalls of the electrically conductive posts as well as sidewalls of the optional thermal paddle. Typically, the stress-release dielectric layer is made of a different material than the crack-inhibiting dielectric frame, and may be composed of an organic material incorporating electrically insulative fillers with low coefficients of thermal expansion (CTE) to alleviate internal expansion and shrinkage of the stress-release dielectric layer during thermal cycling. The electrically insulative fillers may have CTE less than 20 ppm. Further, to absorb stress during resin deposition, the stress-release dielectric layer may have an elastic modulus lower than 30 Gpa. The optional interfacial dielectric layer is located between the stress-release dielectric layer and the second wiring structure and may be made of the same material as the stress-release dielectric layer.

The electrically conductive posts and the optional thermal paddle are spaced apart from each other and may be formed collectively by metal etching. The electrically conductive posts can provide vertical electrical conduction, and typically have top surfaces substantially coplanar with the top surface of the stress-release dielectric layer. The optional thermal paddle can have a top side located at a level between the top and bottom surfaces of the electrically conductive posts and a bottom side substantially coplanar with the bottom surfaces of the electrically conductive posts. The optional thermal paddle offers locally high heat conduction channels for the electrically connectable entity embedded in the cavity defined by an inner surrounding sidewall of the stress-release dielectric layer and the top side of the optional thermal paddle as the bottom of the cavity. For applications with lower thermal requirements, the thermal paddle may be omitted, and the bottom of the cavity may be substantially coplanar with bottom surfaces of the electrically conductive posts.

The embedded electrically connectable entity may be a wiring bridge configured to provide routing traces that are finer than those of the first and second wiring structures. More specifically, the wiring bridge may include a carrier plate (such as, a silicon-based carrier plate) and a routing structure on the carrier plate. The routing structure provides the conductive pads for electrical connection with the first wiring structure. The wiring bridge may further include metallized through-vias that extend through the carrier plate to provide electrical connection between the routing structure and the second wiring structure.

The first and second wiring structures are electrically connected to each other by the electrically conductive posts, and each typically includes at least one dielectric layer and at least one layer of conductive traces. The dielectric layer and the conductive traces are serially formed in an alternate fashion and can be in repetition if needed for further signal routing. The dielectric layer provides a reliable platform for circuitry deposition thereon and may be made from a filler-free organic material to prevent filler particles from contributing to the layer's susceptibility to cracking. Preferably, the dielectric layer is made of an organic material containing reinforcement configured to suppress crack propagation. The innermost dielectric layer of the first wiring structure extends laterally above the top side of the embedded electrically connectable entity and the top surfaces of the at least one crack-inhibiting dielectric frame, the electrically conductive posts and the stress-release dielectric layer and further extends into remaining spaces within the cavity. The innermost conductive traces of the first wiring structure extend laterally over the innermost dielectric layer and are electrically connected to the conductive pads of the embedded electrically connectable entity and the electrically conductive posts through conductive vias in the innermost dielectric layer. The innermost dielectric layer of the second wiring structure extends laterally below the bottom side of the embedded electrically connectable entity and the bottom surfaces of the at least one crack-inhibiting dielectric frame, the electrically conductive posts and the stress-release dielectric layer. The innermost conductive traces of the second wiring structure extend laterally underneath the innermost dielectric layer and are electrically connected to the electrically conductive posts through conductive vias in the innermost dielectric layer. As a result, the first wiring structure can be electrically connected to the embedded electrically connectable entity and to the second wiring structure through the electrically conductive posts. In the instances where the embedded electrically connectable entity includes metallized through vias and no thermal paddle is present below the bottom side of the embedded electrically connectable entity, the innermost dielectric layer of the second wiring structure has a selected portion as a bottom of the cavity for attachment of the embedded electrically connectable entity thereon, and the innermost conductive traces of the second wiring structure includes additional conductive vias in electrical contact with the metallized through vias. In a thermally enhanced configuration where the embedded electrically connectable entity is attached to the top side of a thermal paddle, the second wiring structure may include thermal vias in contact with a bottom side of the thermal paddle to provide heat conduction channels and thereby enhance the thermal performance.

The present invention also provides an assembly, in which one or more external components (e.g. semiconductor devices) are disposed above the first wiring structure and electrically connected to the embedded electrically connectable entity. For instance, one or more semiconductor devices may be face-down coupled to and mounted over the outmost conductive traces of the first wiring structure using soldering materials in contact with the semiconductor devices and the outmost conductive traces. As a result, the semiconductor devices can be electrically connected to the embedded electrically connectable entity. The semiconductor devices can be packaged or unpackaged chips. Furthermore, the semiconductor devices can be bare chips, or wafer level packaged dies, etc.

The assembly can be a first-level or second-level single-chip or multi-chip device. For instance, the assembly can be a first-level package that contains a single chip or multiple chips. Alternatively, the assembly can be a second-level module that contains a single package or multiple packages, and each package can contain a single chip or multiple chips.

The term “cover” refers to incomplete or complete coverage in a vertical and/or lateral direction and includes contact and non-contact situations. For instance, in a preferred embodiment, the stress-release dielectric layer partially covers sidewalls of the electrically conductive posts, with their upper sidewalls completely covered by the stress-release dielectric layer and lower sidewalls covered by the interfacial dielectric layer.

The term “surround” refers to relative position between elements regardless of whether the elements are spaced from or adjacent to one another. For instance, in a preferred embodiment, the stress-release dielectric layer laterally surrounds the embedded electrically connectable entity with the first dielectric layer of the first wiring structure between the stress-release dielectric layer and the embedded electrically connectable entity.

The term “electrically connectable entity” refers to any physical entity capable of forming an electrical connection with the first wiring structure to achieve a desired electrical performance or function. Examples of the electrically connectable entity include, but are not limited to, wiring bridges, passive components, active components and others.

The phrases “mounted over” and “attached on/to/onto” include contact and non-contact with a single or multiple element(s). For instance, in a preferred embodiment, the electrically connectable entity can be attached on the heat conduction surface of the thermal paddle and is separated from the heat conduction surface by the adhesive.

The phrases “electrical connection” and “electrically connected” refer to direct and indirect electrical connection. For instance, in a preferred embodiment, the electrically connectable entity is electrically connected to the electrically conductive posts by the first wiring structure but does not contact the electrically conductive posts.

The spatially relative terms, such as “top”, “bottom”, “below”, “above’, “lower”, “upper” and the like, may be used herein for ease of description to describe one element or feature’s relationship to another element(s) or feature(s) as illustrated in the figures. The spatially relative terms are intended to encompass different orientations of the interconnect board or assembly in use or operation in addition to the orientation depicted in the figures. For example, if the interconnect board or assembly in the figures is turned over, elements described as “below” other elements or features would then be oriented “above” the other elements or features, and “bottom” surfaces would become “top” surfaces. Thus, the example term “below” can encompass both an orientation of above and below. The interconnect board or assembly may be otherwise oriented (rotated 90 degrees or at other orientations) and the spatially relative descriptions used herein interpreted accordingly.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. An interconnect board, comprising electrically conductive posts, at least one crack-inhibiting dielectric frame, a stress-release dielectric layer, an embedded electrically connectable entity, a first wiring structure and a second wiring structure, wherein:
the electrically conductive posts are spaced from each other and from the at least one crack-inhibiting dielectric frame;
the stress-release dielectric layer laterally covers upper sidewall portions of the electrically conductive posts and an inner periphery of the at least one crack-inhibiting dielectric frame and has inner surrounding sidewalls around a cavity;
the embedded electrically connectable entity is disposed within the cavity and includes conductive pads on a top side thereof;
the first wiring structure covers the top side of the embedded electrically connectable entity and top surfaces of the electrically conductive posts, the at least one crack-inhibiting dielectric frame and the stress-release dielectric layer and is electrically connected to the conductive pads of the embedded electrically connectable entity and the electrically conductive posts; and
the second wiring structure covers a bottom side of the embedded electrically connectable entity and bottom surfaces of the electrically conductive posts, the at least one crack-inhibiting dielectric frame and the stress-release dielectric layer and is electrically connected to the electrically conductive posts.

2. The interconnect board of claim 1, wherein the embedded electrically connectable entity is a wiring bridge that includes a routing structure configured with the conductive pads.

3. The interconnect board of claim 2, wherein the wiring bridge includes a silicon-based carrier plate and the routing structure on the silicon-based carrier plate.

4. The interconnect board of claim 1, wherein the at least one crack-inhibiting dielectric frame includes an outer crack-inhibiting dielectric frame around a compartment for accommodating the electrically conductive posts, the embedded electrically connectable entity and the stress-release dielectric layer therein.

5. The interconnect board of claim 1, wherein the at least one crack-inhibiting dielectric frame includes an inner crack-inhibiting dielectric frame with inner and outer peripheries laterally covered by the stress-release dielectric layer.

6. The interconnect board of claim 1, wherein the at least one crack-inhibiting dielectric frame includes an outer crack-inhibiting dielectric frame and an inner crack-inhibiting dielectric frame surrounded by and spaced from the outer crack-inhibiting dielectric frame.

7. The interconnect board of claim 1, further comprising an interfacial dielectric layer that is located between the stress-release dielectric layer and the second wiring structure and laterally covers lower sidewall portions of the electrically conductive posts.

8. The interconnect board of claim 1, further comprising a thermal paddle with a top side as a bottom of the cavity and a bottom side substantially coplanar with the bottom surfaces of the electrically conductive posts, and the embedded electrically connectable entity is attached on the top side of the thermal paddle.

9. The interconnect board of claim 8, wherein the second wiring structure is thermally conductive to the thermal paddle with thermal vias in contact with the bottom side of the thermal paddle.

10. The interconnect board of claim 1, wherein the at least one crack-inhibiting dielectric frame has an elastic modulus lower than 50 Gpa.

11. The interconnect board of claim 1, wherein the at least one crack-inhibiting dielectric frame is an organic material with a reinforcement configured to suppress crack propagation.

12. The interconnect board of claim 1, wherein the stress-release dielectric layer has an elastic modulus lower than 30 Gpa.

13. The interconnect board of claim 1, wherein the stress-release dielectric layer is an organic material with electrically insulative fillers.

14. The interconnect board of claim 1, wherein the first wiring structure includes a first dielectric layer and first conductive traces, the first dielectric layer extends laterally above the top side of the embedded electrically connectable entity and the top surfaces of the at least one crack-inhibiting dielectric frame, the electrically conductive posts and the stress-release dielectric layer and further extends into remaining spaces within the cavity, and the first conductive traces extend laterally over the first dielectric layer and are electrically connected to the conductive pads of the embedded electrically connectable entity and the electrically conductive posts through first conductive vias in the first dielectric layer.

15. The interconnect board of claim 14, wherein the first dielectric layer is an organic material with a reinforcement configured to suppress crack propagation.

16. The interconnect board of claim 1, wherein the second wiring structure includes a second dielectric layer and second conductive traces, the second dielectric layer extends laterally below the bottom side of the embedded electrically connectable entity and the bottom surfaces of the at least one crack-inhibiting dielectric frame, the electrically conductive posts and the stress-release dielectric layer, and the second conductive traces extend laterally underneath the second dielectric layer and are electrically connected to the electrically conductive posts through second conductive vias in the second dielectric layer.

17. The interconnect board of claim 16, wherein the second dielectric layer is an organic material with a reinforcement configured to suppress crack propagation.

18. A semiconductor assembly, comprising:
the interconnect board of claim 1; and
one or more semiconductor devices disposed above the first wiring structure and electrically connected to the embedded electrically connectable entity through the first wiring structure.
